(19) United States
(12) Patent Application Publication
(10) Pub. No.: US 2025/0243127 A1
(43) Pub. Date: Jul. 31, 2025

(54) METHOD OF ENHANCING ROOM-TEMPERATURE PLASTICITY IN BRITTLE CERAMICS AND CERAMICS PRODUCED THEREBY

(71) Applicant: Purdue Research Foundation, West Lafayette, IN (US)

(72) Inventors: Xinghang Zhang, West Lafayette, IN (US); Zhongxia Shang, West Lafayette, IN (US); Haiyan Wang, West Lafayette, IN (US); Chao Shen, Mesa, AZ (US); Anyu Shang, West Lafayette, IN (US)

(73) Assignee: Purdue Research Foundation, West Lafayette, IN (US)

(21) Appl. No.: 19/040,821

(22) Filed: Jan. 29, 2025

Related U.S. Application Data
(60) Provisional application No. 63/627,016, filed on Jan. 30, 2024.

(51) Int. Cl. C04B 41/00; B28B 11/00; C04B 35/10; C04B 35/46

(52) U.S. Cl. CPC C04B 41/0081; B28B 11/005; C04B 35/10; C04B 35/46; C04B 2235/3217; C04B 2235/3232; C04B 2235/604

(57) ABSTRACT

A method for increasing the room temperature ductility of an object made of a ceramic material is disclosed. The method includes providing an object made of a ceramic material, heating the object made of the ceramic material to a temperature to or above the brittle to ductile transition temperature of the ceramic material, introducing defects into the microstructure of the object by deforming the object at the temperature, and cooling the object to room temperature, resulting in room-temperature ductility higher than the room-temperature ductility of the object prior to the heating and deforming steps. A ceramic material subjected to the above-described method of achieving room-temperature ductility is also disclosed. An object made of ceramic material subjected to the above-described method of achieving room-temperature ductility is also disclosed.

### CROSS-REFERENCE TO RELATED APPLICATIONS

The present U.S. patent application is related to and claims the priority benefit of U.S. Provisional Patent Application Ser. No. 63/627,016, filed Jan. 30, 2024, the contents of which are hereby incorporated by reference in their entirety into the present disclosure.

### STATEMENT REGARDING GOVERNMENT FUNDING

This invention was made with government support under N00014-17-1-2087, N00014-22-1-2160, N00014-20-1-2043 and N00014-20-1-2659 awarded by the U.S. Office of Naval Research. The government has certain rights in the invention.

### TECHNICAL FIELD

The present disclosure generally relates to methods of achieving room temperature plasticity in brittle ceramic.

### BACKGROUND

This section introduces aspects that may help facilitate a better understanding of the disclosure. Accordingly, these statements are to be read in this light and are not to be understood as admissions about what is or is not prior art.

Ceramics are widely used as structural materials in industry due to their superior mechanical strength, chemical inertness, electrical insulation, and thermal stability. However, the inherent brittleness limits their widespread applications. In general, most ceramic materials are brittle when tested at low-to-intermediate temperatures due to limited defects to accommodate plasticity with few exceptions. In most cases, dislocations are rarely observed in ceramics during deformation at room temperature (RT) due to the ultra-high resolved shear stress required for the dislocation nucleation, which can be close to the theoretical shear strength for perfect crystals. The yield strength (determined by the critical resolved shear stress for shearing of atomic planes) is often greater than the fracture strength (tensile separation of atomic planes). Moreover, dislocation glide is discouraged at RT as the lattice friction stress is high. In contrast, dislocations in metallic materials are mobile due to low friction stress, leading to improved plasticity. Therefore, the combination of high friction stress and obstacles for dislocation nucleation results in the brittle nature of most ceramic materials at RT. While most semiconductors and ceramic insulators are known to be brittle at low-to-intermediate temperatures, exceptions have been reported in certain ceramics, for example, SrTiO₃, where dislocations carry the room-temperature plasticity. However, the plasticity starts to diminish at intermediate temperatures, leading to brittle behavior. This ductile-to-brittle transition hinders its application at elevated temperatures. Meanwhile, some plasticity observed in α-Ag2S with a relatively low melting point (Tm=825° C.), was attributed to the weak structural and chemical bonding.

Besides the aforementioned ceramics, there have been numerous attempts to improve the deformability of ceramics, however, with limited successes. For example, plasticity has been previously reported in small-size ceramic samples under submicron scales, such as 1 μm micropillars and 25 nm nanowires of GaAs, as well as ZrC with dimensions smaller than 0.55 μm. Ceramic composites have been widely explored, where the ductile second phases in the matrix can deflect cracks, but they don't necessarily improve the plasticity of the ceramic matrix. Another way to enhance the deformability of certain ceramic systems is through grain refinement, where spark plasma sintering is commonly utilized to achieve a compact microstructure with a small grain size. Grain boundary sliding and rotation have been introduced in multiple systems along with several demonstrations of superplasticity at high temperatures. An emerging technique, flash sintering, has been shown to produce defects in ceramics during the nonequilibrium and ultrafast sintering process and can facilitate inelastic deformability compared with conventional sintering methods. For example, flash-sintered 3YSZ has shown enhanced mechanical deformability linked to flash sintering induced dislocations and point defects in YSZ; abundant stacking faults (SFs) and dislocations have been observed in flash-sintered TiO₂, ZnO, and Al₂O₃ that are believed to be responsible for the enhanced RT deformability. However, challenges remain in the generalization and scalability of the flash sintering method as it is mostly demonstrated in oxides with ongoing efforts to improve sample uniformity and scalability. Thus there is an unmet need for more generalized approaches for improving RT deformability in a broad range of ceramics.

### SUMMARY

A method for increasing the room temperature ductility of an object made of a ceramic material is disclosed. The method includes providing an object made of a ceramic material, heating the object made of the ceramic material to a temperature to or above the brittle to ductile transition temperature of the ceramic material, introducing defects into the microstructure of the object by deforming the object at the temperature, and cooling the object to room temperature, resulting in room-temperature ductility higher than the room-temperature ductility of the object prior to the heating and deforming steps.

A ceramic material subjected to the above-described method of achieving room-temperature ductility is also disclosed. An object made of ceramic material subjected to the above-described method of achieving room-temperature ductility is also disclosed.

### BRIEF DESCRIPTION OF DRAWINGS

While some of the figures shown herein may have been generated from scaled drawings or from photographs that are scalable, it is understood that such relative scaling within a figure is by way of example, and are not to be construed as limiting. In these figures the symbol ε has been used.

FIG. 1 shows schematic representation s of the comparison of micropillars compressed at RT (room temperature) with and without the treatment of preloading at elevated temperature (the pillar top is upright). (HT=high temperature)

FIG. 2 shows Uniaxial in situ microcompression tests on the single crystal (SC) TiO₂ at room temperature, 600° C., and 600° C. preloading/RT compression at a constant strain rate of 5×10⁻³ s⁻¹. (A-D) A representative stress-strain curve of SC TiO₂ tested at RT. The pillars experienced brittle failure at the strain of ˜3% accompanied by the propagation of cracks. (E-H) For micropillars tested at 600° C., the shear band emerged at the strain of 6%. Evident shear bands were generated with successive compression without brittle failure. The pillar has a flow stress of ˜1.0 GPa. (I-L) Micropillars were first compressed at 600° C. to the yield point and cooled to the RT. During the RT compression test, flow stress increased continuously to 6.5 GPa, accompanied by serrations and low drops. Shear bands were generated and the compressive strain reached 10% without brittle failure.

FIG. 3 shows TEM micrograph showing defects formation in SC TiO₂ micropillar after elevated temperature preloading and elevated temperature preloading/RT compression (All the pillar top is upright). Section A shows Low-magnification TEM micrograph of a pillar preloaded to 2.5% strain at 600° C. A high density of dislocations nucleated on the pillar top as Sections B and C show magnified TEM images from the zone axis shows high-density dislocations. Section D shows low-magnification TEM micrograph of a pillar compressed to ˜5.5% strain at RT after elevated temperature preloading. Shear bands formed throughout the entire pillar. A higher density of defects was generated near the pillar top compared to the pillar bottom. Sections E and F are TEM micrographs of a pillar compressed to ˜11% strain at RT after elevated temperature preloading. A portion of the single-crystal TiO₂ on the bottom half of the pillar underwent grain fragmentation.

FIG. 4 shows Uniaxial in situ microcompression tests on the SC Al₂O₃ at room temperature, 740° C., and RT compression after elevated temperature preloading at a constant strain rate of 5×10⁻³ s⁻¹. Sections A-D show a representative stress-strain curve of SC Al₂O₃ tested at RT along with SEM snapshots show the pillars experienced a catastrophic brittle failure at the strain of 4% throughout the entire pillar. Sections E-K show a representative stress-strain curve of SC Al₂O₃ micropillars tested at 740° C. along with SEM snapshots; cracks initiated at a strain of ˜7%. The pillar has a flow stress of 1 GPa at a strain of 12%. Sections L-R show stare-strain curves and SEM snapshots fere micropillars which were first preloaded at 740° C. to the yield point and cooled to the RT to continue the RT compression test. Many microcracks were generated under further RT loading. The pillar experienced failure at a strain of 6%.

FIG. 5 shows TEM and SEM micrograph showing defects formation in SC Al₂O₃ micropillar after elevated temperature preloading and elevated temperature preloading/RT compression (the pillar top is upright in all images and the compression direction is from pillar top to the bottom). Section A shows a Bright-field (BF) TEM micrograph of the micropillar shows the formation of obvious twin boundaries from the top right corner to the middle. Section B shows a magnified TEM image of the parallel twin boundaries. Section C shows a High-resolution TEM micrograph shows the twin boundary decorated with stacking faults. Section D shows the corresponding IPF exhibits the defective twin boundaries with serrated steps. Section E shows low-magnification TEM micrograph of a pillar compressed to ˜7% strain at RT after elevated temperature preloading showing the intersection of two slip bands. Section F shows a magnified TEM image of the high-density dislocations formed near the pillar top and the middle of the pillar. Section G shows a dark-field (DF) TEM micrograph showing the dissociation of full dislocations into two partials. Section H shows an IPF exhibiting some subgrain rotation near the pillar top. Section I shows an SEM micrograph showing a pillar compressed to 5% with a dilated top and the intersected twin boundaries appeared on the peripheral surface. Sections J-K are bright-field TEM micrographs showing more dislocations concentrated near the twin boundary located at the pillar bottom. Section L is a BF TEM micrograph showing a deflected microcrack was decorated with a high density of dislocations.

### DETAILED DESCRIPTION

For the purposes of promoting an understanding of the principles of the disclosure, reference will now be made to the embodiments illustrated in the drawings and specific language will be used to describe the same. It will nevertheless be understood that no limitation of the scope of the disclosure is thereby intended, such alterations and further modifications in the illustrated device, and such further applications of the principles of the disclosure as illustrated therein being contemplated as would normally occur to one skilled in the art to which the disclosure relates.

This detailed description is supported by several experiments, materials, methods, tests and test results leading to this disclosure. Ceramic materials with high strength and chemical inertness are widely used as engineering materials. However, the brittle nature limits their applications as fracture occurs before the onset of plastic yielding. There has been limited success despite extensive efforts to enhance the deformability of ceramics. Here we report a method for enhancing the room temperature plastic deformability of ceramics by artificially introducing abundant defects into the materials via preloading at elevated temperatures. After the preloading treatment, single crystal (SC) TiO₂ exhibited a significant increase in deformability, achieving 10% strain at room temperature. SC α-Al₂O₃ also showed plastic deformability, 6-7.5% strain, by using the preloading strategy. These preinjected defects enabled the plastic deformation process of the ceramics at room temperature. These findings suggest a great potential for defect engineering in achieving plasticity in ceramics at room temperature.

Interestingly, despite the limited RT deformability, under elevated temperatures, ceramics can become more deformable and even ductile due to the activation of slip systems and nucleation of numerous defects. The critical resolved shear stress (CRSS) required to initiate plastic deformation decreases at higher temperatures, allowing for the slip to occur more readily. For example, it has been reported that the CRSS of SC MgO·Al₂O₃ decreases by 2 orders of magnitude for {110} slip when temperature increases from 200 to 1,900° C. Meanwhile, the CRSS of SC sapphire for both basal and prismatic slip drastically decreases at elevated temperature following a temperature-dependent logarithmic law.

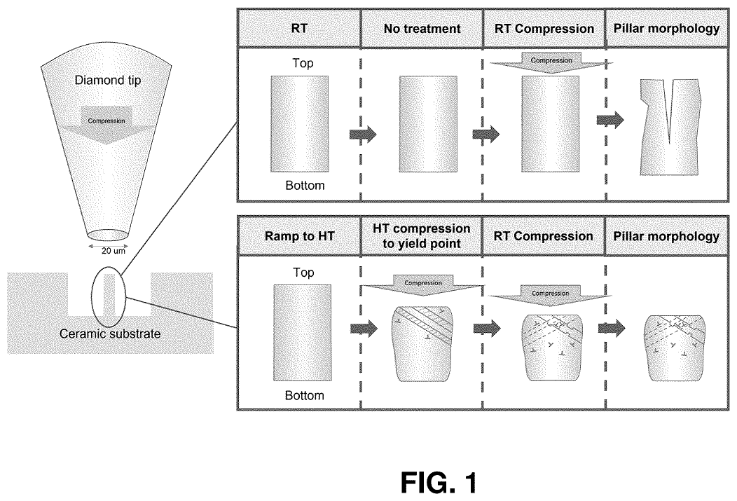

This disclosure describes a generalized concept to improve RT plasticity in ceramics, i.e., using an elevated temperature preloading method to artificially introduce abundant defects into ceramics under elevated temperature and thus significantly improve their RT deformability. In this disclosure the symbol ε is used to represent strain. FIG. 1 shows schematic representation s of the comparison of micropillars compressed at RT (room temperature) with and without the treatment of preloading at elevated temperature (the pillar top is upright). (HT=high temperature). As illustrated in FIG. 1, during the elevated temperature preloading stage (beyond plastic yielding), numerous defects, including dislocation segments, SFs, and twins, can be introduced into the ceramic materials. These defects introduced during elevated temperature preloading contributed prominently to the plastic deformability of ceramics at RT. To validate this concept, we have selected TiO₂ and Al₂O₃ model systems as they are typical engineering ceramics. For example, TiO₂ has been extensively studied considering its physical, optical, electronic, and catalytic properties. A temperature-dependent study on the mechanical properties from RT to 1,300° C. suggests that TiO₂ starts to deform plastically above 600° C. Similarly, Al₂O₃ is a very popular elevated temperature engineering ceramic material with a wide range of applications. Under elevated temperatures (>600° C.), basal slip in the a-direction is the preferred deformation mechanism in Al₂O₃ to accommodate some plasticity. However, at RT, little dislocation activity has been reported and brittle failure dominates in Al₂O₃. in situ SEM compression test and detailed microstructural characterizations of the deformed pillars were done to compare the effectiveness of the preloading methods on RT deformability. The experimental findings suggest that elevated temperature preloading can be an effective approach to enhance the deformability of ceramics at RT. This concept can be applied to a wide range of ceramics for improving their deformability at RT.

The materials and methods and tests utilized in experiments leading to this disclosure will now be described: Micropillars of SC (001) TiO₂ and SC (0001) Al₂O₃ with a dimension of ˜3 μm in diameter and ˜6 μm in height (a diameter-to-height aspect ratio of ˜1:2) were fabricated using a focused ion beam (FIB) in a Thermo Fischer Quanta 3D FEG scanning electron microscope. A series of decreasing currents were utilized to mill the pillar with the least tapering angles in a concentric and annular crater. In situ SEM micropillar compression experiments were performed inside the Quanta 3D FEG microscope using a Hysitron PI 88×R PicoIndenter to collect the force-displacement data. For elevated temperature in situ compression setups, the 20 μm diameter diamond flat punch was fixed on the probe heater, and the specimens were clamped on a ceramic heating stage tightly by V-shaped molybdenum. Before the compression test, the temperature on both the heating stage and probe heater was simultaneously ramped up at a rate of 10° C./min and isothermally stabilized for 30 min to eliminate the thermal-driven drifts. An average drift rate of less than 0.5 nm/s and an estimated force noise level of less than 8 μN were monitored during the alignment preloading process for 45 s. When the temperature of both sample stage and indenter tip reached the preset values and remained stable for 30 min, preloading compression began by compressing the pillar using a diamond flat punch tip at a constant strain rate of 5×10⁻³ s⁻¹. The selection of the strain rate was within the range of the typical quasistatic uniaxial compression test. Upon detecting the yielding phenomenon from the load-displacement curve (typically at a plastic strain of 2-3%), the preloading procedure was terminated. Afterwards, the samples were cooled down to RT for subsequent testing. An overestimation of specimen displacement during the compression test induced by a displacement associated with the measuring instrument (machine compliance) was systematically corrected.

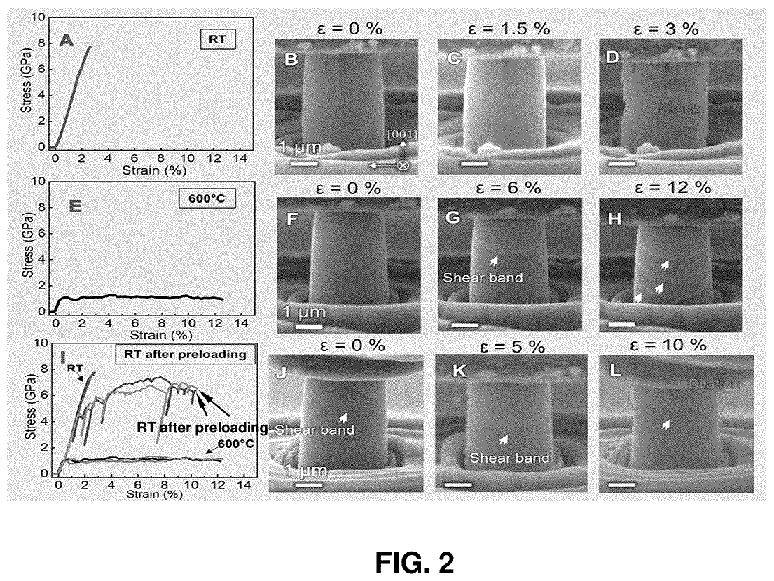

In situ microcompression tests of SC (001) TiO₂: SC (001) TiO₂ micropillar specimens tested at three different deformation conditions are referred to as DT1 (deformation at RT), DT2 (deformation at 600° C.), and DT3 (preloading at 600° C. to just beyond yielding, cooled to RT, and followed by RT compression). All deformation experiments were performed at a constant strain rate of 5×10⁻³ s⁻¹. FIG. 2 shows Uniaxial in situ microcompression tests on the single crystal (SC) TiO₂ at room temperature, 600° C., and 600° C. preloading/RT compression at a constant strain rate of 5×10⁻³ s⁻¹. Sections A-D of FIG. 1 show a representative stress-strain curve of SC TiO₂ tested at RT and the pillars at different strains. The pillars experienced brittle failure at the strain of ˜3% accompanied by the propagation of cracks. Sections E-H of FIG. 1 show a representative stress-strain curve for micropillars tested at 600° C., and the pillars at different strains. The shear band emerged at the strain of 6%. Evident shear bands were generated with successive compression without brittle failure. The pillar has a flow stress of ˜1.0 GPa. Sections I-L of FIG. 1 show a representative stress strain curve for micropillars first compressed at 600 ° C. to the yield point and cooled to the RT., and the pillars at different strains. During the RT compression test, flow stress increased continuously to 6.5 GPa, accompanied by serrations and low drops. Shear bands were generated, and the compressive strain reached 10% without brittle failure.

As shown in FIG. 2, during the deformation of DT1 specimens at RT, all pillars experienced brittle failure at a strain of 3% or less at ultrahigh flow stress of nearly 8 GPa accompanied by the propagation of large cracks (Sections A-D of FIG. 2). During the testing of the DT2 specimen at 600° C., pillars underwent plastic deformation. Shear bands emerged at 6% strain and propagated downward under successive compression to 12% strain (Sections E_H of FIG. 2). Flow stress reached a plateau of 1.0 GPa. In contrast, during the testing of the DT3 specimen, flow stress increased continuously to ˜6.5 GPa. Small serrations and multiple large load drops were observed in the stress-strain curves. Pillars deformed at RT sustained a giant strain of nearly 10% without noticeable major cracks. The in-situ SEM snapshots of a representative DT3 pillar show the propagation of multiple shear bands with a dilated pillar top; while no obvious crack was detectable from the pillar surface (Sections I-L of FIG. 2).

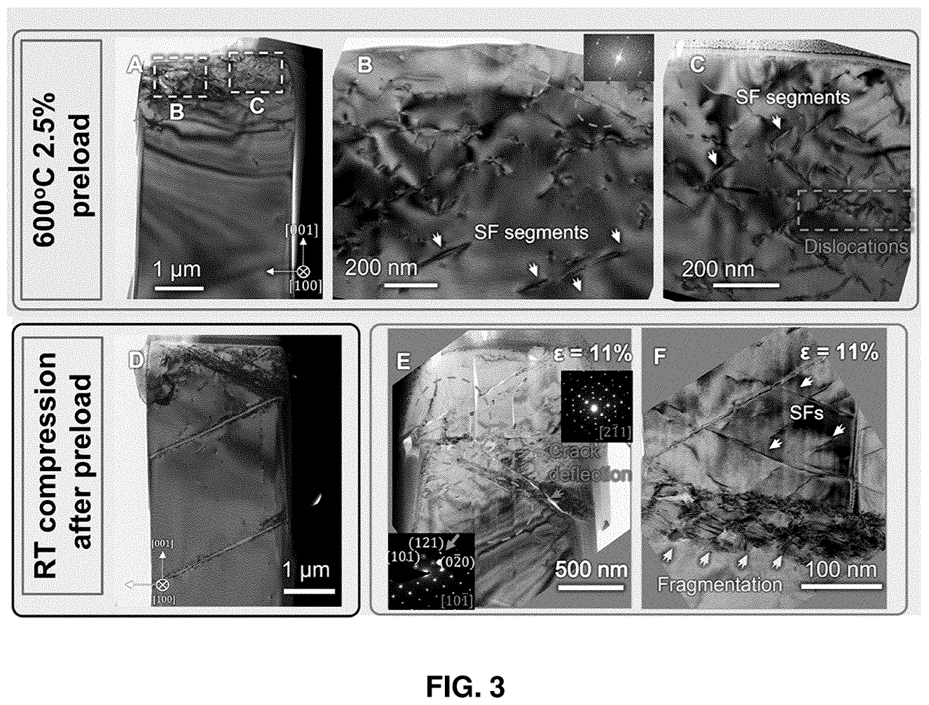

Bright-field (BF) TEM micrographs showed that the DT1 TiO₂ pillar contains strain contours and scattered dislocations when deformed to ε=3% (onset of catastrophic fracture). To investigate the influence of preloading on the RT deformability, post-mortem TEM analyses were also performed on the DT2 and DT3 pillars of SC TiO₂. FIG. 3 shows TEM micrograph showing defects formation in SC TiO₂ micropillar after elevated temperature preloading and elevated temperature preloading/RT compression (All the pillar top is upright). Numerous dislocations, as well as SF segments, were introduced near the pillar top after the DT2 specimen was plastically deformed to 2.5% strain at 600° C. (Sections A-C of FIG. 3). Meanwhile, for the DT3 specimen compressed to ε=5.5% at RT (after 600° C. preloading), the presence of several dark bands after compression suggested highly defective area, containing several stacking faults and dislocation networks throughout the entire pillar (Section D of FIG. 3). The slip bands contained abundant dislocations and SFs and became broader while propagating from the upper left corner to the lower right portion of the pillar top.

Meanwhile, these dislocation-rich slip bands intersected and blocked the propagation of microcracks. When the DT3 pillars were compressed to an even greater strain, 11%, several phenomena were observed. First, in addition to the inclined microcracks, vertical microcracks appeared (Section E of FIG. 3). These microcracks were, however, terminated at ˜1 μm from the pillar top surface by dislocation bands (Section D of FIG. 3). Second, crack deflection occurred at the intersection between vertical cracks and dislocation bands. The inclined microcracks were decorated with high-density dislocation bands as well as some SFs and propagated to the lower right portion of the pillar to a depth of 2 μm (or 33% of the entire pillar height). Third, grain fragmentation (labeled by arrows in section F of FIG. 3) was observed near the middle section of the deformed pillar, leading to subgrains with small grain sizes, as evidenced by polycrystalline SAED pattern in further studies. The BF TEM image and inverse pole figure (IPF) map exhibited the formation of subgrains with minor grain rotation ( ). The Kernel average misorientation (KAM) map indicates a high degree of misorientation) and the formation of some low-angle grain boundaries (LAGBs) were observed near the subgrains.

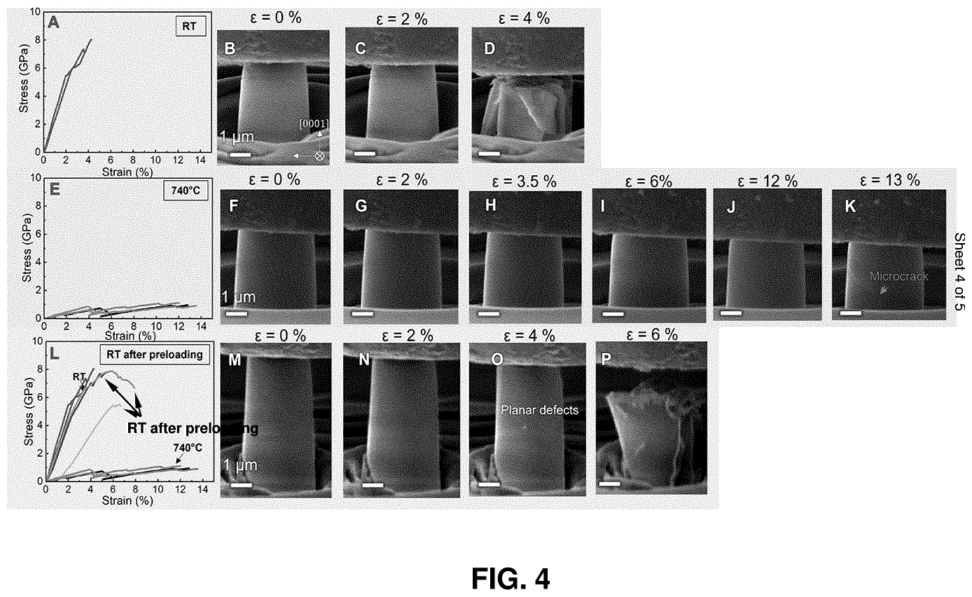

In situ microcompression tests of SC (0001) Al₂O₃: To explore the general applicability of the concept of preloading improved plasticity in ceramics, similar preloading experiments were performed in SC Al₂O₃. In this case, SC (0001) Al₂O₃ specimens were tested at three deformation conditions, referred to as DA1 (deformation at RT), DA2 (deformation at 740° C.), and DA3 (preloading at 740° C. to slightly beyond plastic yielding, cooled to RT, followed by RT compression) specimen, at a constant strain rate of 5×10⁻³ s⁻¹. As shown in section A of FIG. 4, during the RT deformation of the DA1 specimens, all pillars fractured at the strain of 3-4%, reaching a high fracture strength of ˜8 GPa. In situ SEM micrographs in sections B-D of FIG. 4 show catastrophic failure and giant cracks completely disintegrated the pillar. During the deformation of DA2 pillars at 740° C., the flow stress reduced significantly to 1 GPa accompanied by serrations (section E of FIG. 4). In situ SEM snapshots (sections F-I of FIG. 4) showed the pillars plastically deformed prominently as evidenced by the dilation of pillar top without crack when ε≤6%. Microcracks emerged when ε=7%, and few microcracks were visible on the pillar surface when ε=12-13% (Sections J-K of FIG. 4). In comparison, the DA3 pillar reached a flow stress of 4.5-8 GPa and a fracture strain of 6-7.5% (Section L of FIG. 4). Cracks were not observed in the pillar deformed to a strain of 4% (sections M_O of FIG. 4). Microcracks then propagated gradually and slowly in the lower half of the pillar until the pillar fractured when ε=6% (section P of FIG. 4).

It was also determined that the SC Al₂O₃ DA1 pillar deformed at RT to a maximum fracture strain of 3% without any preloading treatment. BF-TEM images showed short dislocation segments scattered in the upper half of the pillar, while some giant transgranular cracks propagated throughout the entire pillar. IPF map indicated that the crack penetration to the pillar interior leads to a minor texture change and little crystal rotation. The KAM map indicates scattered dislocations. The Geometrically necessary dislocation (GND) map showed that GNDs were mostly distributed near the pillar top and along the cracks.

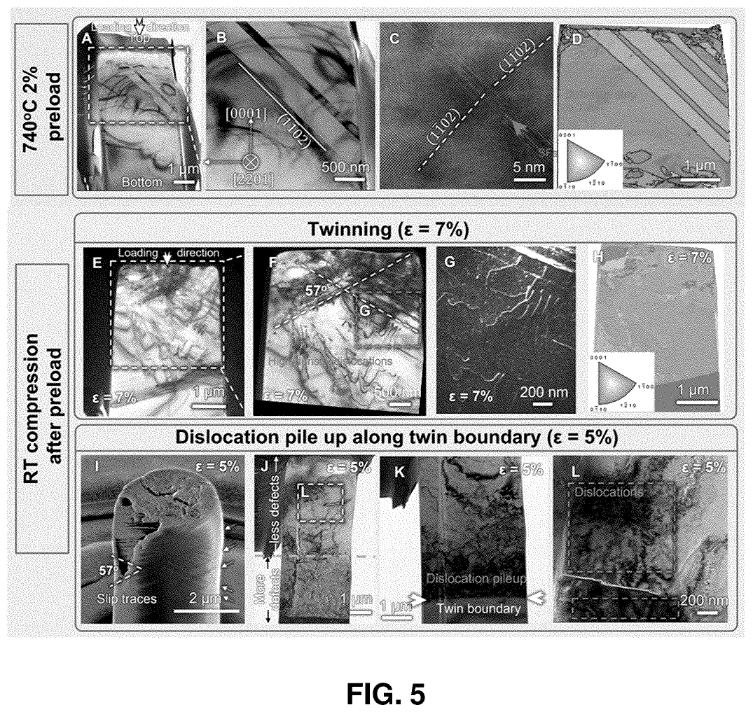

Post-mortem microstructure analyses were performed on the SC Al₂O₃ DA2 and DA3 micropillars to investigate the influence of preloading on the microstructure evolution. As shown in BF TEM micrographs in sections A-B of FIG. 5 for the DA2 pillar preloaded to the strain of 2% at 740° C., multiple parallel rhombohedral twins formed and extended to a depth of 3 μm from the pillar top. The high-resolution TEM micrograph in section C of FIG. 5 shows that the twin boundary was decorated with SFs. The corresponding high-resolution IPF map (with a spatial resolution of 6 nm captured from NanoMegas ASTAR procession electron diffraction) in section D of FIG. 5 confirms the formation of numerous nanotwins with thickness varying from 13 to 45 nm. Furthermore, the high-resolution IPF map shows that these twin boundaries are defective, as indicated by serrated steps on twin boundaries (section A of FIG. 4). The KAM map indicates that a high degree of misorientation happened near the pillar top. Meanwhile, GNDs mostly formed near the pillar top and along the twin boundaries). For the DA3 pillar that underwent deformation to a strain of 7%, abundant dislocations were observed (section E of FIG. 5). BF TEM micrograph in section F of FIG. 5 shows two groups of SFs intersected with each other. Meanwhile, a high density of wavy dislocations was generated and interacted with the SFs, as shown in the dark-field TEM micrograph in section G of FIG. 5. The IPF map in section H of FIG. 5 composes two similar colors as section D of FIG. 5, where is the matrix and the other represents the plastically deformed region due to twinning. The IPF map shows that a large portion of the entire pillar has undergone significant plastic deformation. The deformed region has expanded to 2-3 μm from the pillar top. Non-twin orientation region was also detected, indicating local crystal reorientation. SEM image of another pillar compressed to 5% strain in section I of FIG. 5 shows a dilated pillar top and the intersected slip bands appeared on the pillar surface. The SEM image from different viewing angles showed slip trace intersection, and rhombohedral twins blocked the crack propagation. The BF and Dark-field (DF) TEM micrographs of the deformed pillar in sections J and K of FIG. 5 show a high density of dislocations concentrated, however, near a twin boundary located at the lower portion of the deformed pillar. The BF TEM micrograph in section L of FIG. 5 shows an inclined microcrack that has propagated nearly horizontally and was decorated with a high density of dislocations. Meanwhile, a deformation-induced plastic zone was observed in front of an intersected crack tip,

The micropillar compression studies of this disclosure show that SC TiO₂ experienced brittle failure when tested at RT. The poor deformability of the pristine pillar is a result of the aforementioned lack of capability for the nucleation and glide of dislocations. Surprisingly, substantial plasticity was observed in the preloaded pillar under RT compression, where the pillars were plastically deformed to 10% strain without catastrophic failure (section I of FIG. 2). Meanwhile shear bands and the dilation of pillar tops were observed (sections K and L of FIG. 2). Similar phenomena were present in Al₂O₃, which is known for its brittle behavior at RT. At RT, the SC Al₂O₃ pillars underwent catastrophic failure at 4% strain. However, after the preloading treatment, prominent improvement in plasticity was observed. For instance, the pillars remained intact when ε=4%, and fractured at 6%. Both studies suggest that the preloading treatment is sufficient to significantly improve the RT plasticity of brittle ceramic materials. The mechanisms behind the improved plasticity in these ceramic materials are discussed below.

Defect-assisted room-temperature (RT) plasticity in preloaded SC TiO₂: Compared to pristine ceramics with few defects, abundant defects, such as dislocation seeds and twin boundaries, were introduced in the pillars during the preloading at elevated temperatures. These defects allow ceramics to bypass the large CRSS required for dislocation nucleation at RT, therefore when the preloaded pillars containing dislocations were deformed at RT, plastic deformation took place. It has been reported that under the uniaxial compression along direction between 300˜1,300° C., SC TiO₂ deformed by {101̅}<101> slip, but no plasticity in SC TiO₂ has been reported at RT to date. In the current study, subgrains appeared after RT deformation and dislocations were generated within one subgrain. In comparison, numerous dislocation seeds were introduced into the SC TiO₂ pillar after being compressed at 600° C. during the preloading stage as shown in sections A_C of FIG. 3. Given the compression axis of the rutile SC TiO₂ is along direction and the calculation of the largest resolved shear stress, dislocations could have a Burgers vector of <101> as widely reported previously. Meanwhile, SF segments were observed near the pillar top. Once the preloaded TiO₂ pillar was further deformed at RT, the scattered dislocation seeds and SF segments aligned and propagated along the easy slip systems, leading to slip bands and SF ribbons. These dislocation activities accommodate the plasticity manifested as the dilation of the pillar top.

Work hardening is frequently observed in ductile metallic materials due to the formation of forest dislocations. In contrast, work hardening is rare in ceramics, especially at RT due to the aforementioned brittle nature of ceramics. Hence it is unexpected that the preloaded TiO₂ pillars show prominent work hardening phenomenon as shown in section I of FIG. 2. After careful examination of TEM micrographs in TiO₂ pillars deformed to a strain of 5.5% (sections D, E of FIG. 3), we found that upon successive loading, more dislocations and SFs were generated on inclined/intersecting slip planes. The intersection of slip bands has several consequences. First, slip bands due to the formation of high-density dislocations or SFs form barriers for the transmission of dislocations on inclined slip systems. Prior studies show that the SFs can intercept the transmission of dislocations, and contribute to strengthening and prominent work hardening in metallic materials. Second, the intersection of inclined SFs leads to immobile dislocations, such as Lomer dislocations, these sessile dislocations increase the barrier for the migration of partials and consequently increase the work hardening rate. Apart from the strengthening effect, one of the key mechanisms for SF induced plasticity is attributed to the defaulting process where dislocations can glide along SFs, leading to substantial plasticity. Upon substantial gliding of dislocations along SFs in the same direction, shear bands may emerge. Recently, Li et al. reported RT plasticity in flash-sintered polycrystalline TiO₂ and they show that the test temperature prominently changes the deformation mechanisms and stress-strain behavior. At RT, deformation induces abundant SFs with nanoscale spacing. However, only moderate work hardening was observed. In this case, different work hardening may arise from the difference in dislocation density. It is observed that more dislocation seeds nucleated in addition to the SFs in the preloaded TiO₂ compared to the flash sintered TiO₂. Such a high defect density in preloaded specimens may lead to more interactions between dislocations and SFs and a greater working hardening ability than the flash-sintered TiO₂.

Next, we examine the influence of dislocation slip bands on crack propagation in ceramics. Cracking is a prevalent deformation mechanism in ceramics when deformed at RT. Microcracks were also observed in TiO₂ pillars deformed to a strain of 5.5%. Section E of FIG. 3 shows some of the microcracks were blocked by intersecting slip bands. It is likely that the intersection of slip bands generated the stress localization at the intersection, which initiated the microcrack formation along the slip bands and at the intersections. The blockage of microcracks by dislocation slip bands is another evidence of improved plasticity in TiO₂ pillars deformed at RT.

In addition to work hardening and blockage of microcracks, another deformation mechanism may have also been triggered to improve RT plasticity in TiO₂. As shown in sections E and F of FIG. 3, at even greater plastic strain, 11%, many microcracks emerged and they occurred along planes that have experienced large shear strains (evidenced by residual dislocations near the microcracks). Some of the inclined microcracks appeared to encounter each other and changed their propagation path to either vertical or lateral directions. At some of the microcrack intersected regions, grain fragmentation took place. These subgrains were isolated by the obvious slip bands or microcracks, as shown in section F of FIG. 3.

Defect-assisted RT plasticity in preloaded SC Al₂O₃: Similarly, the preloading concept appears effective to improve the RT plasticity of SC Al₂O₃. Some parallel rhombohedral twin boundaries as well as dislocation seeds were embedded into SC Al₂O₃ during elevated temperature preloading to 2% strain as shown in sections A_D of FIG. 5. In SC Al₂O₃, it was reported that twinning stress for rhombohedral twins is constant, ˜12.6 MPa, between 900 K and 1373 K when the mechanical loading is parallel to the c-axis, while twinning stress rapidly increases as the temperature decreases below 900 K. A zonal dislocation mechanism was proposed to explain the preference for rhombohedral twins over dislocation slip. As the fault energy caused by the partials in the oxygen lattice is too high, the dissociation of colinear partials 1/6 <01̅11> is suppressed. Consequently, the dissociation to a zonal partial with Burgers vector of 1/21.9 <01̅11> is preferred, which activates the formation of rhombohedral twins. A competing theory of shuffling mechanism may explain the formation of rhombohedral twins as well. Interfacial dislocations at the coherent twin boundaries form steps that promote twinning or detwinning. The glide of interfacial dislocations followed by shuffling in every five-atom group (containing 2 Al and 3 O atoms) leads to the formation of rhombohedral twins upon mechanical loading.

It should be noted that the IPF map (section D of FIG. 5 shows the nanotwins (labeled in orange color) introduced in preloaded SC Al₂O₃ have thickness varying from tens of nm to hundreds of nm. Furthermore, the high-resolution IPF map also showed numerous steps on the coherent twin boundaries. Defective twin boundaries have been observed in nanotwinned metals and these steps contain mobile Shockley partials that promote plasticity in nanotwinned metals.

Once the preloaded pillar was further compressed to 7% strain at RT, two sets of inclined SFs were observed to intersect with each other (sections E, F of FIG. 5). Such a phenomenon is similar to the intersecting defects observed in SC TiO₂ DT3 specimen preloaded and then deformed at RT (sections D and E of FIG. 3). Dark-field TEM micrograph in section G of FIG. 5 also reveals curved dislocations, indicating the activation of full dislocations in SC preloaded Al₂O₃ during deformation at RT. The weak-beam, dark-field (WBDF) TEM micrographs indicate that the dislocations in DA3 have two possible Burgers vectors, namely <101̅1> and 1/3<022̅1> In this case, the possible slip systems are {011̅2}/<101̅1> and {011̅2}/1/3<2̅021>, in good agreement with previous findings.

Comparing to the IPF map in preloaded SC Al₂O₃ (to a strain of 2% at 740° C.) in FIG. 5D, the orange-colored region in the RT deformed preloaded specimens to 7% strain (section H of FIG. 5) occupied nearly the entire pillar top. Such an observation suggests that twinning remains one of the dominant deformation mechanisms. The propagations of partials on defective twin boundaries were intense enough to change the orientation of the matrix to the twin variant. Such a significant twinning process leads to prominent RT plasticity. For some dislocations that nucleated in the matrix during preloading, when they glide on the twin boundaries under shear stresses, detwinning can also take place, leading to the formation of steps on the twin boundaries. It is also possible that the defective TBs act as a source to emit some mobile dislocations which prefer to glide on the planes that are inclined with respect to TBs. The interaction of partials on intersecting twinning planes can result in Lomer-lock, leading to strengthening or work hardening. The work hardening phenomenon, though not as prominent as those in TiO₂, has indeed been observed in SC Al₂O₃ as shown in section I of FIG. 4.

Another dislocation enabled plasticity mechanism has been observed in SC Al₂O₃. After the preloaded SC Al₂O₃ is deformed at RT to a strain of 5%, significant dilation of the pillar top was observed, and slip traces from two intersecting twin planes were also revealed on the pillar surface (section I of FIG. 5). Interestingly but counterintuitively, abundant dislocations were observed near the lower portion of the deformed pillar, whereas the dilated pillar top contains fewer dislocations, The migration of partials along twin boundaries will lead to the exit of these partials from pillar surfaces, leaving behind slip traces. Such an exhaustion of dislocation by deformation of SC pillars has been observed in metallic materials, and the phenomenon is referred as to mechanical annealing, or deformation-induced depletion of dislocations in single crystals due to the free surface effect. The remaining dislocations in the pillar propagate downward driven by continuous loading. These dislocations were clearly obstructed by the TB existing at the lower portion of the pillar. Such a twin boundary barricades the propagation of dislocations, leading to their pile-up (section K of FIG. 5) Therefore, the dislocation density is high near the twin boundary (section K of FIG. 5).

While the influence of preloading on nucleation of dislocations has been confirmed in this study on two model systems, TiO₂ and Al₂O₃, the mobility of dislocation is also curtailed by lattice friction stress. The significant RT plasticity observed in preloaded TiO₂ and Al₂O₃ implies that the lattice friction stress in these ceramics may have been reduced. Several factors may play an important role. First, partial dislocations are prevalent in the deformed TiO₂ and Al₂O₃. It is known that the friction stress for partials is lower than perfect dislocations because the dislocation core width is broader for partials. Second, our ASTR IPF studies show that TBs in preloaded Al₂O₃ have steps. Such defect TBs have been shown to be the source for mobile partials, and thus enable prominent plasticity in twinned metallic materials. Third, it has been shown that the dislocation core in Al₂O₃ can be non-stoichiometric. Edge dislocation can dissociate into two partials on adjacent glide plane and thus improve the mobility of dislocations at elevated temperatures. It is likely that such unique dislocation cores created during preloading at elevated temperature have been preserved at room temperature, and thus enable the dislocation mobility at RT. RT plasticity has been reported in flash-sintered polycrystalline TiO₂ by Li et. al. Flash sintering, a non-equilibrium sintering technique, introduces abundant dislocations as well as oxygen vacancies during the sintering process. These defects can accommodate mechanical deformation and improve plasticity at RT. In flash-sintered ceramics, it is likely that oxygen vacancies and other charged point defects have reduced the friction stress for migration of dislocations. Similarly, It was reported that the ductility of the ferroelectric oxides Pb(In_{1/2}Nb_{1/2})O₃—Pb(Mg_{1/3}Nb_{2/3})O₃—PbTiO₃ can be improved by introducing more oxygen vacancies into the system, where the covalent bonding was dramatically weakened. Oxygen vacancies could also be introduced during the preloading stage under elevated temperatures and the vacuum condition in the SEM chamber. Considering our testing conditions, i.e., the temperature of 600° C. for 30 min under the vacuum of 1×10⁻⁶ torr, the estimated diffusion length is much less than 0.4 μm. Thus, such oxygen vacancy effects could be mostly on the surface but not on the entire pillar properties. In this case, the oxygen vacancies play a minor role comparing to those of high-density dislocations and stacking faults observed in the preloading pillars. Compared to flash sintering, the preloading concept is more general and can be widely utilized in a broad range of ceramic materials, including those that cannot be easily flash sintered.

Furthermore, to demonstrate the potential of the preloading method on improving the deformability of polycrystalline ceramics, similar preloading experiments were performed on a polycrystalline TiO₂ bulk sample prepared by spark plasma sintering (SPS). Larger pillars with ˜7 μm in diameter and a height of 14 μm (a diameter-to-height aspect ratio of ˜1:2) were fabricated from the sample. Based on the preliminary data studied, it was obvious that the as-processed SPS TiO₂ pillars were brittle when tested directly at RT, and the specimens fractured instantaneously and catastrophically. Micropillar compression tests at 600° C. show substantial plasticity. In comparison, subsequent room temperature compression tests on the preloaded pillar have endured a few percent of plastic strain before fracture, indicating the preloading treatment also improves the RT plasticity of the polycrystalline bulk samples. In this case, the orientation effects and size effects on the improved plasticity are considered to be minimal. Such studies suggest the preloading concept may be further scaled up to produce bulk ceramics or specific sections of large specimens and parts with prominent RT plasticity.

Thus, this disclosure demonstrates that defects can be introduced into the ceramics through preloading treatment under elevated temperatures for improving the RT deformability of high temperature ceramics. It is important to note that selecting an appropriate preloading temperature is crucial. If the temperature is below the brittle-to-ductile transition temperature, defects, including dislocations and SFs, will not form and thus will not improve the RT plasticity. However, if the preloading temperature is too high, some of the defects induced during preloading could be eliminated through annihilation process, reducing the impact of the preloading experiments on plasticity.

Thus, this disclosure describes and implements the concept that room-temperature plasticity in ceramics can be achieved by introducing mobile dislocations through an elevated temperature preloading approach. The in situ micropillar compression tests indicate that the SC TiO₂ and SC Al₂O₃ can achieve substantial plasticity at RT if high density defects were introduced during the elevated temperature preloading. These pre-loading introduced mobile dislocations also allowed us to observe several interesting plastic deformation mechanisms at RT in ceramics, including the migration of SFs and twin boundaries and work hardening through the interaction of these defects, a tribute that has long been the privilege of ductile metallic materials. Introducing the preloading concept to bulk polycrystalline ceramics, as this disclosure demonstrated, could present great potential towards future designs of bulk ductile ceramics.

Based on the above description, it is an objective of this disclosure to describe a method for increasing the room temperature ductility of an object made of a ceramic material. The method contains the steps of providing an object made of a ceramic material; heating the object made of the ceramic material to a temperature to or above the brittle to ductile transition temperature of the ceramic material; introducing defects into the microstructure of the object by deforming the object at the temperature; and cooling the object to room temperature, resulting in room-temperature ductility higher than the room-temperature ductility of the object prior to the heating and deforming steps. In some embodiments of the method of this disclosure, the ceramic material is titanium dioxide (TiO₂). In some embodiments of the method of this disclosure, the ceramic material is Aluminum oxide (Al₂O₃). In some embodiments of the method, the temperature to which the object is heated is 10-50 degrees C. higher than the brittle-ductile transition temperature. As a guiding principle, the temperature to which the object is heated should be such that the defects such as dislocations, stacking faults and twins can form as result of deformation at that temperature. In some embodiments of the method of this disclosure, the deformation of the object is by compression. In many embodiments of the methods of this disclosure defects are introduced by deformation. Non-limiting examples of such defects are dislocations, stacking faults, and twins. In some embodiments of this disclosure, the resulting deformation strain at room temperature is 3.3 times higher than the deformation strain at room temperature prior to heating the object. In some embodiments of the methods of this disclosure, the resulting deformation strain at room temperature is 3.3 times higher than the deformation strain at room temperature prior to heating the object.

It is another objective of this disclosure to describe a ceramic material subjected to the methods of this disclosure. It is yet another objective of this disclosure to describe an object made of a ceramic material subjected to the methods of achieving room temperature ductility described above. In some embodiments of the object of this disclosure, the ceramic material is a structural material. In some embodiments of the object of this disclosure, the object is a structural component. In some embodiments of this disclosure the ceramic material subjected to the methods of this disclosure is TiO₂ or Al₂O₃.

While the present disclosure has been described with reference to certain embodiments, it will be apparent to those of ordinary skill in the art that other embodiments and implementations are possible that are within the scope of the present disclosure without departing from the spirit and scope of the present disclosure. Thus, the implementations should not be limited to the particular limitations described. Other implementations may be possible. It is therefore intended that the foregoing detailed description be regarded as illustrative rather than limiting. Thus, this disclosure is limited only by the following claims.

1. A method for increasing the room temperature ductility of an object made of a ceramic material, comprising:
providing an object made of a ceramic material;
heating the object made of the ceramic material to a temperature to or above the brittle to ductile transition temperature of the ceramic material;
introducing defects into the microstructure of the object by deforming the object at the temperature.
cooling the object to room temperature, resulting in room-temperature ductility higher than the room-temperature ductility of the object prior to the heating and deforming steps.

2. The method of claim 1, wherein the ceramic material is titanium dioxide (TiO₂)

3. The method of claim 1, wherein the ceramic material is Aluminum oxide (Al₂O₃)

4. The method of claim 1, wherein the temperature is 10-50 degrees C. higher than the transition temperature.

5. The method of claim 1, wherein the deformation of the object is by compression.

6. The method of claims 1, 2, or 4, wherein the defects introduced are dislocations and/or stacking faults.

7. The method of claims 1, 3, or 4, wherein the defects introduced are dislocations and/or twins.

8. The method of claims 1, 2, 3, 4, or 5, wherein the resulting deformation strain at room temperature is 3.3 times higher than the deformation strain at room temperature prior to heating the object.

9. (canceled)

10. A ceramic material subjected to the method of claim 1.

11. An object made of a ceramic material and subjected to the method of claim 1.

12. The object of claim 11, wherein the ceramic material is a structural material.

13. The object of claim 11, wherein the object is a structural component.

14. The ceramic material of claim 10, wherein the ceramic material is TiO₂ or Al₂O₃.

15. The object of claim 11, wherein the ceramic material is TiO₂ or Al₂O₃.
